(19) United States
(12) Patent Application Publication
(10) Pub. No.: US 2010/0126759 A1
(43) Pub. Date: May 27, 2010

(54) STRUCTURE OF MULTI-LAYER PRINTED CIRCUIT BOARD

(75) Inventors: Shih-Chieh Chao, Taipei (TW); Chih-Wen Huang, Taipei (TW); Chun-Lin Liao, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: Tatung Company, Taipei (TW)

(21) Appl. No.: 12/409,519

(22) Filed: Mar. 24, 2009

(30) Foreign Application Priority Data
Nov. 27, 2008 (TW) 97146039

(51) Int. Cl. H05K 1/16

(52) U.S. Cl. 174/260

(57) ABSTRACT

A structure of a multi-layer printed circuit board includes a power layer, a ground layer, and a dielectric layer. The dielectric layer is located between the power layer and the ground layer. The dielectric layer has a relative permittivity and a relative permeability, wherein the product of the relative permittivity and the relative permeability substantially decreases along with an increase in frequency within a frequency range.

### CROSS-REFERENCE TO RELATED APPLICATION

This application claims the priority benefit of Taiwan application serial no. 97146039, filed Nov. 27, 2008. The entirety of the above-mentioned patent application is hereby incorporated by reference herein and made a part of specification.

### BACKGROUND OF THE INVENTION

1. Field of the Invention

The present invention relates to a structure of a circuit board, and more particularly, to a structure of a multi-layer printed circuit board (PCB).

2. Description of Related Art

FIG. 1 is a cross-sectional view illustrating a structure of a conventional multi-layer PCB. Referring to FIG. 1, the structure of the conventional multi-layer PCB 100 includes a first component layer 110, a ground layer 120, a dielectric layer 130, a power layer 140, and a second component layer 150. The ground layer 120, the dielectric layer 130, and the power layer 140 are disposed between the first component layer 110 and the second component layer 150. The dielectric layer 130 is disposed between the ground layer 120 and the power layer 140. Generally, in the structure of the conventional multi-layer PCB 100, the dielectric layer 130 is often made of epoxy resin bonded glass fabric material. Thereby, the dielectric layer 130 has a rather low conductivity when working on a direct current (DC) condition, and a DC-bias level between the ground layer 120 and the power layer 140 can be maintained in the circuitry. In addition, the first component layer 110 and the second component layer 150 are mainly formed for accommodating electronic devices (not shown) that are electrically connected to one another through metal wiring (not shown).

Practically, the structure of the multi-layer PCB 100 further includes two dielectric layers 132 and 134 respectively disposed between the first component layer 110 and the ground layer 120 and between the power layer 140 and the second component layer 150 as shown in FIG. 1. The dielectric layers 132 and 134 are frequently made of the same material as that of the dielectric layer 130 in most cases.

During operation of circuits in the multi-layer PCB, electromagnetic noises mostly generate from some devices having high-speed digital signals or great output power, such as pulse generators, power amplifiers, and so on. As the electromagnetic noises are generated in the aforesaid devices, the electromagnetic noises are transmitted on the circuit board in form of electromagnetic waves and interfere with other devices on the circuit board.

In terms of electromagnetism, the ground layer 120 and the power layer 140 are respectively disposed on and below the dielectric layer 130, thus constituting a parallel plate transmission line structure. Since the parallel plate transmission line structure has zero cut-off frequency, electromagnetic waves at any frequency can propagate therein. That is to say, when the electromagnetic noises are generated, the electromagnetic noises mainly propagate through the parallel plate transmission line in the structure of the multi-layer PCB 100.

In order to reduce the electromagnetic interferences, decoupling capacitors are often used for filtering the electromagnetic noises. Nonetheless, due to the equivalent serial inductance (ESL) of the capacitor, the useful filtering bandwidth of the decoupling capacitor is usually below 500 MHz.

Alternatively, in order to avoid the electromagnetic noises propagating through the parallel structure formed by the power layer 140 or the ground layer 120, slots are cut on the power layer 140 or the ground layer 120. However, inappropriate cutting is apt to enlarge the return current paths of neighboring circuits and induces high order electromagnetic resonances. Hence, it is more difficult to predict distribution of electromagnetic noises.

On the other hand, the pertinent art has proposed increasing permittivity of a dielectric substrate, such that an equivalent capacitance between the power layer and the ground layer is increased. Thereby, the electromagnetic noises can be better restricted. Nevertheless, according to research results, the resonant frequency of the electromagnetic noises is shifted from a high frequency band to a relatively low frequency band by applying said solution proposed by the pertinent art. As such, resonant frequency effects of the structure of the multi-layer PCB 100 become more complicated.

### SUMMARY OF THE INVENTION

In view of the above, the present invention is directed to a structure of a multi-layer PCB capable of effectively reducing electromagnetic interferences by means of dispersive properties of a dielectric layer.

In the present invention, a structure of a multi-layer PCB including a power layer, a ground layer, and a dielectric layer is provided. The dielectric layer is located between the power layer and the ground layer. The dielectric layer has a relative permittivity and a relative permeability, wherein the product of the relative permittivity and the relative permeability substantially decreases along with an increase in frequency within a frequency range.

According to an embodiment of the present invention, the maximum product of the relative permittivity and the relative permeability is at least three times the minimum product of the relative permittivity and the relative permeability within the frequency range.

According to an embodiment of the present invention, the frequency range is substantially from 0 Hz to 1 GHz.

According to an embodiment of the present invention, at least a dispersive material is doped into the dielectric layer.

According to an embodiment of the present invention, the dispersive material doped into the dielectric layer has a volume percentage more than 0% but less than or equal to 75%.

According to an embodiment of the present invention, the dispersive material is a magnetic material.

According to an embodiment of the present invention, the magnetic material is at least one of ferrum (Fe), cobalt (Co), and nickel (Ni).

According to an embodiment of the present invention, the structure of the multi-layer PCB further includes a filter. The filter is suitable for filtering electromagnetic signals at a frequency equal to or lower than 500 MHz.

According to an embodiment of the present invention, the filter is a decoupling capacitor.

According to an embodiment of the present invention, the filter at least includes a decoupling capacitor and at least a resistor coupled in series.

According to an embodiment of the present invention, in the structure of the multi-layer PCB, the dielectric layer disposed between the power layer and the ground layer is made of a selected material. Within a certain frequency range, the product of the relative permittivity and the relative permeability of the dielectric layer substantially decreases with the increase in frequency. Besides, the filter is formed in the structure of the multi-layer PCB. Therefore, the electromagnetic noises can be effectively reduced.

In order to make the aforementioned and other features and advantages of the present invention more comprehensible, several embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIG. 1 is a cross-sectional view illustrating a structure of a conventional multi-layer PCB.

FIG. 2A is a schematic view illustrating a structure of a multi-layer PCB according to an embodiment of the present invention.

FIG. 2B is a top view illustrating the structure of the multi-layer PCB depicted in FIG. 2A.

FIG. 3 illustrates the frequency characteristic of the transmission coefficient of a multi-layer PCB.

FIG. 4 illustrates the frequency dependency of the relative permeability of the nickel metal.

FIG. 5 illustrates the frequency dependency of the product of a relative permittivity and a relative permeability of the dielectric layer.

FIG. 6 illustrates the frequency characteristic of the electromagnetic transmission coefficient of a multi-layer PCB according to an embodiment of the present invention.

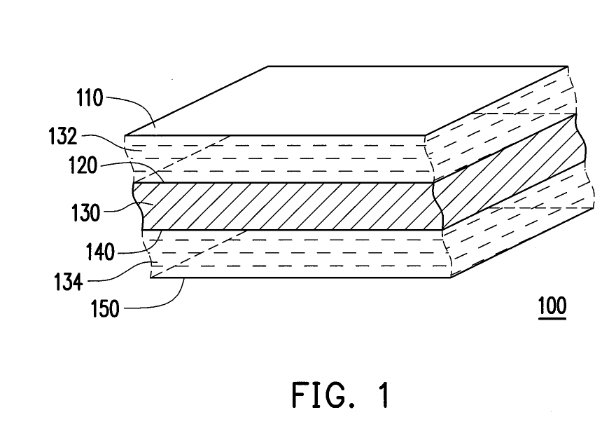

### DESCRIPTION OF EMBODIMENTS

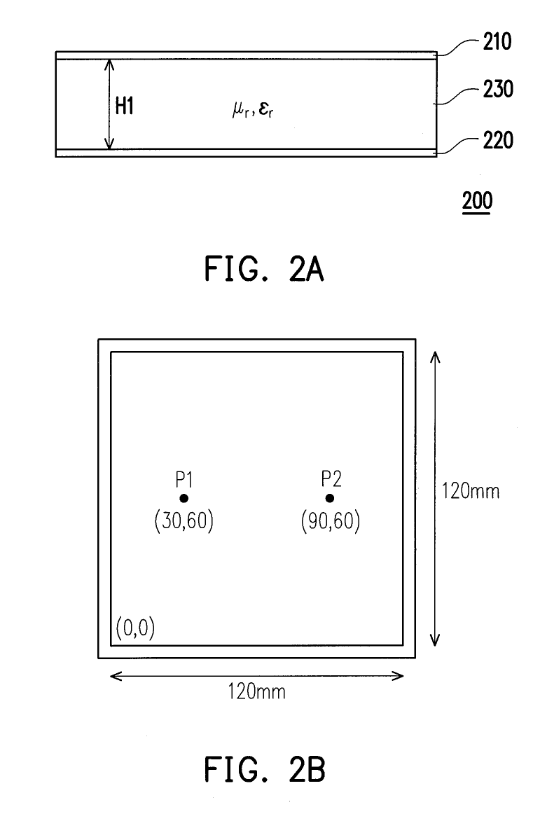

FIG. 2A is a schematic view illustrating a structure of a multi-layer PCB according to an embodiment of the present invention. Referring to FIG. 2A, the structure of the multi-layer PCB 200 includes a power layer 210, a ground layer 220, and a dielectric layer 230. The dielectric layer 230 is located between the power layer 210 and the ground layer 220. The dielectric layer 230 has a relative permittivity ∈ᵣ and a relative permeability μᵣ, wherein the product of the relative permittivity ∈ᵣ and the relative permeability μᵣ substantially decreases along with an increase in frequency within a frequency range.

In general, a frequency corresponding to electromagnetic resonance in the structure of the multi-layer PCB 200 is closely associated with a dimension of the structure of the multi-layer PCB 200. Given that the structure of the multi-layer PCB 200 has a maximum side length L, the structure of the multi-layer PCB 200 is in a fundamental resonant mode when the wavelength of the electromagnetic wave is approximately twice the side length L. Namely, L=λ/2.

Here, the resonance frequency is

$${f}_{res} = \frac{C}{λ} = \frac{1}{\sqrt{μ \cdot ɛ} \cdot 2 L}$$

The propagation velocity of the electromagnetic wave in the structure of the multi-layer PCB 200 is

$$C = \frac{1}{\sqrt{μ \cdot ɛ}} = \frac{1}{\sqrt{{μ}_{o} \cdot {ɛ}_{o}} \cdot \sqrt{{μ}_{r} \cdot {ɛ}_{r}}} = {C}_{o} \cdot \frac{1}{\sqrt{{μ}_{r} \cdot {ɛ}_{r}}}$$

Here, Cₒ is a speed of light under a vacuum condition, ∈ᵣ refers to the relative permittivity of a material of the dielectric layer 230, and μᵣ refers to the relative permeability.

Based on the above, the equation of the resonant frequency fᵣₑₛ can be rewritten as the following:

$${f}_{res} = \frac{C}{λ} = \frac{1}{\sqrt{{μ}_{r} \cdot {ɛ}_{r}}} \cdot \frac{{C}_{o}}{2 L} \qquad ( 1 )$$

It can be learned from the equation (1) that the relative permittivity ∈ᵣ and the relative permeability μᵣ of the dielectric layer 230 are closely related to the resonant frequency in the structure of the multi-layer PCB 200. In brief, the greater the product of the relative permittivity ∈ᵣ and the relative permeability μᵣ is, the lower the resonant frequency is.

Each parameter affecting the propagation of the electromagnetic noises in the structure of the multi-layer PCB 200 is analyzed by numerical method as indicated below. Here, a transmission coefficient S₂₁ in an electromagnetic scattering parameter denotes a noise isolation effect between any two ports on the structure of the multi-layer PCB 200. When the transmission coefficient S₂₁ is reduced, electromagnetic transmission between the two ports becomes lower, thus increases the isolation.

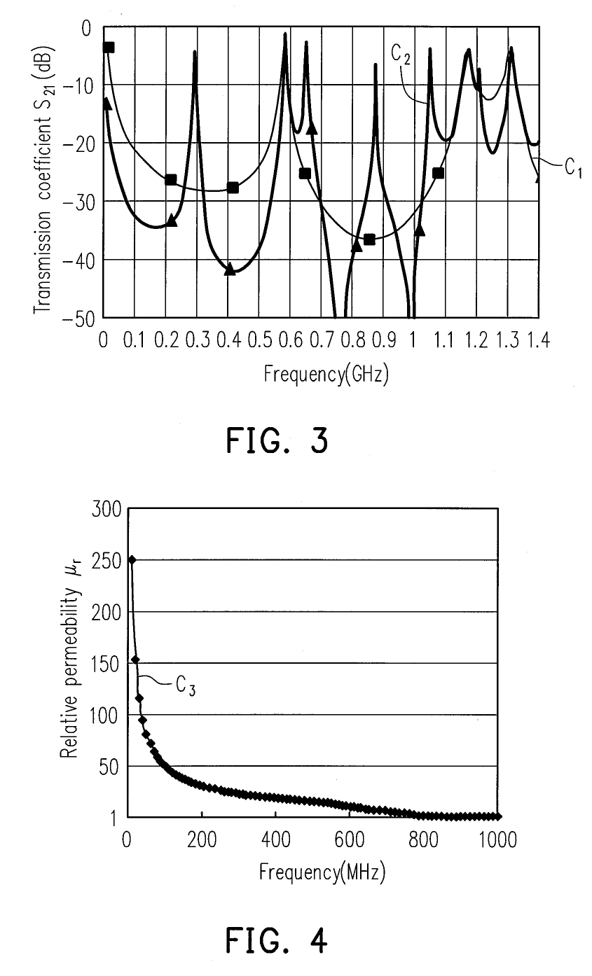

FIG. 2B is a top view illustrating the structure of the multi-layer PCB depicted in FIG. 2A. FIG. 3 illustrates a correlation between a transmission coefficient and a frequency of the structure of the multi-layer PCB depicted in FIG. 2A. Referring to FIGS. 2A, 2B, and 3, the length and the width of the structure of the multi-layer PCB 200 are both 120 mm in the present embodiment, for example. The thickness Hi (as shown in FIG. 2A) of the dielectric layer 230 is, for example, 0.8 mm. Besides, when the dielectric layer 230 is made of conventional glass fiber (FR4), the relative permittivity ∈ᵣ is 4.4, and the relative permeability μᵣ is 1.0. Both the relative permittivity ∈ᵣ and the relative permeability μᵣ do not vary with the frequency. As such, the frequency characteristic of the transmission coefficient S₂₁ between a first port P1 and a second port P2 in the structure of the multi-layer PCB 200 is represented by a curve C1 as shown in FIG. 3. It can be learned from the curve C1 that the structure of the multi-layer PCB 200 is in the lowest resonant mode at the frequency of 580 MHz approximately. That is to say, a peak of the transmission coefficient S₂₁ between the first port P1 and the second port P2 appears at the frequency of 580 MHz approximately. In other words, the electromagnetic noises at the frequency approximating to 580 MHz are likely to propagate within the structure of the multi-layer PCB 200.

In general, a decoupling capacitor is often used for filtering the electromagnetic noises on the circuit board. However, due to ESL of the decoupling capacitor, only the electromagnetic noises at the frequency of 500 MHz or lower can be suppressed by using the decoupling capacitor. Accordingly, the electromagnetic noises in the structure of the multi-layer PCB cannot be effectively suppressed by using the decoupling capacitor, given that the dielectric layer 230 is made of the conventional glass fiber.

In addition, when the dielectric layer 230 is made of a dielectric material of which the relative permittivity ∈ᵣ is 20 and the relative permeability μᵣ is fixed to be 1.0, the frequency characteristic of the transmission coefficient S₂₁ between the first port P1 and the second port P2 in the structure of the multi-layer PCB 200 is represented by a curve C2 as shown in FIG. 3. It can be deduced from comparison results of the curves C1 and C2 that the lowest electromagnetic transmission coefficient S₂₁ becomes even lower when the relative permittivity ∈ᵣ is raised from 4.4 to 20. For instance, when the frequency is 600 MHz or lower, the lowest electromagnetic transmission coefficient S₂₁ is decreased from −28 dB to −42 dB. However, the absolute value of the peak of the transmission coefficient S₂₁ is not significantly reduced, and the entire frequency response indicates that the resonant frequency is shifted to a lower frequency band. In other words, the frequency in the fundamental resonant mode is reduced to around 290 MHz. Although within said frequency range the decoupling capacitor can be used for filtering, the resonant frequency which used to be in a relatively high frequency mode (1.1 GHz˜1.4 GHz, for example) is shifted to a lower frequency band, thereby the resonance frequency appears more often within the same frequency range (e.g. 700 MHz or lower). That is to say, there are more peaks of the transmission coefficient S₂₁ within the aforesaid frequency range. As such, the additional peaks of the transmission coefficient S₂₁ (high frequency bands of the resonant frequency) are not likely to be remedied by using the decoupling capacitor.

To resolve said problem, the resonant frequency of the structure of the multi-layer PCB in the fundamental resonant mode can be further lowered, while the resonant frequency in a relatively high frequency mode is prevented from being shifted to a lower frequency band. Therefore, the product of the relative permittivity ∈ᵣ and the relative permeability μᵣ has a higher value at the low frequency band and has a lower value at the high frequency band. In other words, the dielectric layer 230 is required to be characterized by prominent dispersion effects. Hence, in an embodiment of the present invention, at least a dispersive material (not shown) is doped into the dielectric layer 230, and the dispersive material doped in the dielectric layer 230 has a volume percentage substantially more than 0% but less than or equal to 75%.

Generally, various materials are able to comply with the requirement for the high relative permittivity ∈ᵣ but they are usually non-dispersive. Therefore, the dispersive material can be a magnetic material, such as Fe, Co, and Ni having distinct dispersive properties contributive to reduction of the relative permeability μᵣ with the increasing frequency. For instance, the relative permeability μᵣ of nickel metal can be rapidly reduced from more than 200 to 50 or lower within the frequency range of 200 MHz, as represented by a curve C3 shown in FIG. 4. It can be learned from the curve C3 that the relative permeability μᵣ of nickel metal is decreased with an increase in frequency.

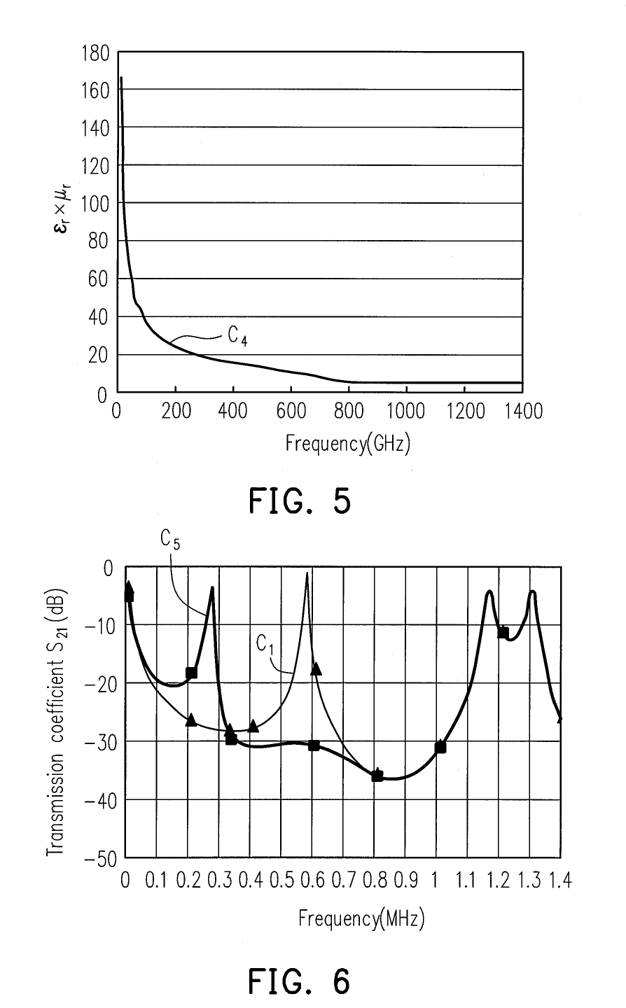

According to an embodiment, when the dielectric layer 230 is made of nickel metal having a volume percentage of 15% and glass fiber having a volume percentage of 85%, the frequency dependency of the product of the relative permittivity μᵣ and the relative permeability μᵣ of the dielectric layer 230 is represented by a curve C4 as shown in FIG. 5. From the curve C4, it is known the product of the relative permittivity ∈ᵣ and the relative permeability μᵣ of the dielectric layer 230 is rapidly decreased with the increase in the frequency. Hence, the fundamental resonant frequency of the structure of the multi-layer PCB 200 can be shifted to a lower frequency band. Besides, the resonant frequency in a relatively high frequency mode (e.g. more than 600 MHz) does not change significantly. That is to say, when the dielectric layer 230 in the structure of the multi-layer PCB 200 is made of the aforesaid dispersive material according to the present embodiment, the frequency characteristic of the electromagnetic transmission coefficient S₂₁ is represented by a curve C5 as shown in FIG. 6.

To be more specific, in FIG. 6, the curve C1 represents the frequency characteristic of the electromagnetic transmission coefficient S₂₁ of the multi-layer PCB when the dielectric layer is made of conventional glass fiber. In addition, the curve C5 represents the frequency characteristic of the electromagnetic transmission coefficient S₂₁ of the multi-layer PCB when the dielectric layer is made of glass fiber having dispersive properties. It can be learned from the curves C1 and C5 that the fundamental resonant frequency is changed from 580 MHz to 295 MHz when the dispersive material is doped into the dielectric layer, while the resonant frequency of the higher mode remains around 1 GHz. As such, given that the structure of the multi-layer PCB 200 further with a filter (not shown), the fundamental resonant frequency at 295 MHz can be easily filtered. In an embodiment, the filter can be a decoupling capacitor. In another embodiment, the filter can also include at least a decoupling capacitor and at least a resistor in series. The type of the filter discussed above is merely exemplary and should not be construed as a limitation to the present invention.

It should be mentioned that the structure of the multi-layer PCB 200 can also be applied to the structure of the conventional multi-layer PCB 100. In particular, the structure of the multi-layer PCB 200 can further include a first component layer (not shown), a second component layer (not shown), and two second dielectric layers (not shown). Here, the structure of the multi-layer PCB 200 is interposed between the first component layer and the second component layer, and the second dielectric layers are respectively disposed between the first component layer and the structure of the multi-layer PCB 200 and between the second component layer and the structure of the multi-layer PCB 200. According to an embodiment, the second dielectric layers can be made of conventional glass fiber or the same material of the dielectric layer 230. The material of the second dielectric layers is merely exemplary and should not be construed as limited to the present invention.

In light of the foregoing, the dielectric layer disposed between the power layer and the ground layer in the structure of the multi-layer PCB is made of a selected material according to the present invention. Within a certain frequency range, the product of the relative permittivity and the relative permeability of the dielectric layer substantially decreases together with the increase in frequency. By using the present invention with suitable filters, the electromagnetic noises generated by the circuit elements of the multi-layer PCB can be effectively filtered.

Though the present invention has been disclosed above by the embodiments, they are not intended to limit the present invention. Anybody skilled in the art can make some modifications and variations without departing from the spirit and scope of the present invention. Therefore, the protecting range of the present invention falls in the appended claims.

What is claimed is:

1. A structure of a multi-layer printed circuit board, comprising:
a power layer;
a ground layer; and
a dielectric layer disposed between the power layer and the ground layer, wherein the dielectric layer has a relative permittivity and a relative permeability, and the product of the relative permittivity and the relative permeability substantially decreases along with an increase in frequency within a frequency range.

2. The structure of the multi-layer printed circuit board as claimed in claim 1, wherein the maximum product of the relative permittivity and the relative permeability is at least three times the minimum product of the relative permittivity and the relative permeability within the frequency range.

3. The structure of the multi-layer printed circuit board as claimed in claim 1, wherein the frequency range is substantially from 0 Hz to 1 GHz.

4. The structure of the multi-layer printed circuit board as claimed in claim 1, wherein at least a dispersive material is doped into the dielectric layer.

5. The structure of the multi-layer printed circuit board as claimed in claim 4, wherein the dispersive material doped into the dielectric layer has a volume percentage more than 0% but less than or equal to 75%.

6. The structure of the multi-layer printed circuit board as claimed in claim 4, wherein the dispersive material is a magnetic material.

7. The structure of the multi-layer printed circuit board as claimed in claim 6, wherein the magnetic material is at least one of ferrum, cobalt, and nickel.

8. The structure of the multi-layer printed circuit board as claimed in claim 1, further comprising a filter suitable for filtering electromagnetic signals at a frequency equal to or lower than 500 MHz.

9. The structure of the multi-layer printed circuit board as claimed in claim 8, wherein the filter is a decoupling capacitor.

10. The structure of the multi-layer printed circuit board as claimed in claim 8, wherein the filter at least comprises a decoupling capacitor and at least a resistor in series.
